(19) United States
(12) Patent Application Publication
(10) Pub. No.: US 2025/0089316 A1
(43) Pub. Date: Mar. 13, 2025

(54) Power Semiconductor Device with Balancing Shunt Structure

(71) Applicant: Wolfspeed, Inc., Durham, NC (US)

(72) Inventors: Charlotte Elizabeth Jonas, Morrisville, NC (US); Joohyung Kim, Cary, NC (US); Sei-Hyung Ryu, Cary, NC (US)

(21) Appl. No.: 18/466,487

(22) Filed: Sep. 13, 2023

(51) Int. Cl. H01L 29/06; H01L 27/06; H01L 27/092; H01L 29/08; H01L 29/423; H01L 29/78

(52) U.S. Cl. CPC H10D 62/127; H10D 30/668; H10D 62/106; H10D 62/154; H10D 62/158; H10D 64/519; H10D 84/811; H10D 84/85

(57) ABSTRACT

Power semiconductor devices are provided. In one example, the power semiconductor device includes a semiconductor structure includes an active region and an inactive region, the active region includes a plurality of unit cells. The power semiconductor device includes a gate structure, wherein at least a portion of the gate structure is on the inactive region. The power semiconductor device includes a first shunt contact structure at least partially on the inactive region. The power semiconductor device includes a second shunt contact structure at least partially on the inactive region. The power semiconductor device includes a balancing shunt structure at least partially on the inactive region.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor device may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or gallium nitride (“GaN”) based semiconductor materials.

### SUMMARY

Aspects and advantages of embodiments of the present disclosure will be set forth in part in the following description, or may be learned from the description, or may be learned through practice of the embodiments.

One example embodiment of the present disclosure is directed to a power semiconductor device. The power semiconductor device includes a semiconductor structure comprising an active region and an inactive region, the active region comprising a plurality of unit cells. The power semiconductor device includes a gate structure, wherein at least a portion of the gate structure is on the inactive region. The power semiconductor device includes a first shunt contact structure at least partially on the inactive region. The power semiconductor device includes a second shunt contact structure at least partially on the inactive region. The power semiconductor device includes a balancing shunt structure at least partially on the inactive region.

Another example embodiment of the present disclosure is directed to a power semiconductor device. The power semiconductor device includes a semiconductor structure comprising an active region and an inactive region, the active region comprising a plurality of unit cells. The power semiconductor device includes a field insulating layer at least partially on the inactive region. The power semiconductor device includes a gate structure at least partially on the field insulating layer. The power semiconductor device includes a shunt contact structure extending at least partially through the field insulating layer. The power semiconductor device includes a balancing shunt structure at least partially on the inactive region.

Another example embodiment of the present disclosure is directed to a power semiconductor device. The power semiconductor device includes a semiconductor structure comprising an active region and an inactive region, the active region comprising a plurality of unit cells. The power semiconductor device includes a gate structure, wherein at least a portion of the gate structure is on the inactive region. The power semiconductor device includes a plurality of shunt contact structures at least partially on the inactive region. The power semiconductor device includes a balancing shunt structure at least partially on the inactive region. The balancing shunt structure is operable to balance a displacement current associated with the plurality of shunt contact structures.

Another example embodiment of the present disclosure is directed to power semiconductor device. The power semiconductor device includes a semiconductor structure comprising an active region and an inactive region, the active region comprising a plurality of unit cells. The power semiconductor device includes a gate pad in a center portion of the power semiconductor device. The power semiconductor device includes a plurality of shunt contact structures at least partially around the gate pad.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a plan view of a semiconductor wafer that includes a plurality of semiconductor devices according to example embodiments of the present disclosure.

FIG. 2A depicts a plan view of one of the semiconductor devices included on the semiconductor wafer of FIG. 1 according to example embodiments of the present disclosure.

FIG. 2B depicts a plan view of the semiconductor device of FIG. 2A according to example embodiments of the present disclosure with the source pad and gate pad metallization removed.

FIG. 3 depicts a plan view of a portion of a unit transistor cell of the power semiconductor device of FIGS. 2A-2B according to example embodiments of the present disclosure.

FIG. 4 depicts a cross-sectional view taken along the line 4-4 of FIG. 3 according to example embodiments of the present disclosure.

FIG. 5 depicts a plan view of an example semiconductor device including a source runner.

FIG. 6 depicts a cross-sectional view taken along the line 6-6 of FIG. 5.

FIG. 7 depicts a cross-sectional view taken along the line 6-6 of FIG. 5 with body diode current flowing through the source runner.

FIG. 8 depicts a plan view of the example semiconductor device of FIG. 5 with bottleneck areas for body diode current highlighted.

FIG. 9 depicts a plan view of an example semiconductor device without a source runner and including a plurality of shunt contact structures.

FIG. 10 depicts a cross-sectional view taken along the line A-A′ of FIG. 9.

FIG. 11 depicts a cross-sectional view taken along the line B-B′ of FIG. 9.

FIG. 12 depicts a plan view of an example semiconductor device without a source runner and including a balancing shunt structure according to example embodiments of the present disclosure.

FIG. 13 depicts a cross-sectional view taken along the line 13-13 of FIG. 12.

FIG. 14 depicts a plan view of an example semiconductor device without a source runner and including a balancing shunt structure according to example embodiments of the present disclosure.

FIG. 15 depicts a plan view of an example semiconductor device without a source runner and including a balancing shunt structure according to example embodiments of the present disclosure.

FIG. 16 depicts a plan view of an example semiconductor device without a source runner according to example embodiments of the present disclosure.

FIG. 17 depicts a plan view of an example semiconductor device including a gate pad in a center portion of the power semiconductor device and having a balancing shunt structure according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

A power semiconductor device may have a semiconductor substrate, such as a silicon carbide substrate having a first conductivity type (e.g., an n-type substrate), on which an epitaxial layer structure having the first conductivity type (e.g., n-type) is formed. A portion of this epitaxial layer structure (which may include one or more separate layers) functions as a drift region of the power semiconductor device. The device typically includes an “active region,” which includes one or more unit cell devices that have a junction such as a p-n junction. The active region may be formed on and/or in the drift region. The active region acts as a main junction for blocking voltage in the reverse bias direction and providing current flow in the forward bias direction. The power semiconductor devices may have a unit cell structure in which the active region of each power semiconductor device includes a plurality of individual unit cell devices that are electrically connected in parallel and that together function as a single power semiconductor device.

Power semiconductor devices are often fabricated from wide bandgap semiconductor materials, such as silicon carbide or Group Ill-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

Power semiconductor devices can have a lateral structure or a vertical structure. In a device having a lateral structure, the terminals of the device (e.g., the drain, gate and source terminals for a power MOSFET device) are on the same major surface (e.g., top surface or bottom surface) of a semiconductor structure. In contrast, in a power semiconductor device having a vertical structure, at least one terminal is provided on each major surface of the semiconductor structure. For instance, in a vertical MOSFET device, the source may be on the top surface of the semiconductor structure and the drain may be on the bottom surface of the semiconductor structure, or vice versa. Herein, the term “semiconductor structure” refers to a structure that includes one or more semiconductor layers, such as semiconductor substrates and/or semiconductor epitaxial layers.

Vertical power semiconductor devices, including a vertical MOSFET, can have a standard gate electrode design in which the gate electrode of the transistor is formed on top of the semiconductor structure. Alternatively, the power semiconductor devices may have the gate electrode in a gate trench within the semiconductor structure. Power semiconductor devices having trench gate electrodes are typically referred to as trench gate devices (e.g., trench gate MOSFETs). With the standard gate electrode design, the channel region of each unit cell transistor is horizontally disposed underneath the gate electrode. In contrast, in the trench gate design, the channel is vertically disposed.

Power silicon carbide MOSFETs are in use today for applications requiring high voltage blocking such as voltage blocking of 5,000 volts or more. By way of example, silicon carbide MOSFETs are commercially available that are rated for current densities of 10 A/cm² or more that will block voltages of at least 10 kV. To form such devices, a plurality of unit cells are formed, where each unit cell includes a MOSFET transistor. In high power applications, a large number of these unit cells (e.g., hundreds or thousands) are typically provided on a single semiconductor substrate, and a gate structure (e.g., gate electrode pattern) is formed on a top side of the semiconductor substrate that acts as the gate electrode for all of the unit cells. The opposite (bottom) side of the semiconductor substrate acts as a common drain for all of the unit cells of the device. A plurality of source contacts are formed on source regions in the semiconductor structure that are exposed within openings in the gate electrode pattern. These source contacts are also electrically connected to each other to serve as a common source. The resulting device has three terminals, namely a common source terminal, a common drain terminal and a common gate electrode that act as the terminals for the hundreds or thousands of individual unit cell transistors. It will be appreciated that the above description is of an n-type MOSFET; the locations of the drain and source would be reversed for a p-type MOSFET.

The gate structure (e.g., gate electrode pattern) of a power MOSFET may be implemented by forming a patterned conductive layer on the semiconductor structure. The patterned conductive layer may include, for instance, a gate pad, one or more gate runners (e.g., gate buses), and a plurality of elongated gate fingers that extend through an active region of the device. In some examples, the patterned conductive layer may include a semiconductor layer such as, for example, a polysilicon layer. The gate pad may be in an inactive region of the device, and each gate finger may connect to the gate pad, either directly or via one or more of the gate runner(s). The gate pad portion of the gate structure may be formed on a thick field insulating layer. The field insulating layer may include, for example, a field oxide layer (e.g., a silicon oxide layer), although other insulating materials or a combination of insulating materials may be used. A metal gate bond pad may be formed on top of a portion of the gate pad and may form an ohmic contact to the gate pad. Bond wires may be attached to the gate bond pad to provide a mechanism for applying a bias voltage to the gate structure of the device.

As discussed above, the gate structure and the metal layers/bond pads for the source, gate and drain are formed on a semiconductor structure. The semiconductor structure has an active region in which the unit cell transistors are formed and an inactive region. The inactive region may include a gate pad portion that is underneath the above-discussed gate bond pad and field insulating layer, a gate runner portion that is underneath the above-discussed gate runners and field insulating layer, and a termination portion (e.g., edge termination portion) that may surround the active region. The gate pad portion of the inactive region of the semiconductor structure that is underneath the gate pad and field insulating layer may include an implanted region in an upper surface of the semiconductor structure. For example, in an n-type MOSFET, a large p-type silicon carbide region is formed via ion implantation in the upper surface of the semiconductor layer structure to form the inactive region. Thereafter, the field insulating layer is formed on this p-type silicon carbide region. During operation, the MOSFET may switch from reverse blocking state (where the device may block a very large voltage and not conduct current) to the on-state (where the device may conduct large currents) in a very short period of time. As the device switches states, a displacement current is generated that flows between the drain terminal on the bottom surface of the device and the source terminal on the upper surface of the device (in an n-type device).

In some instances, the displacement current may flow in the active region of the semiconductor structure and in the inactive region (e.g., beneath the gate structure) of the semiconductor structure. In each case, the magnitude of the displacement current (IDisp) is the product of the change in voltage per unit time (dV/dt) across the p-n junction in the semiconductor layer structure and the capacitance of this p-n junction (Cpn). In other words:

$$IDisp = ( dV / dt ) * Cpn$$

In the active region, there are many paths for the displacement current (since each unit cell includes a pair of source contacts) and the p-n junctions are small (since a width in the horizontal direction of each p-well that forms a p-n junction with an underlying n-type layer may only be, for example, about 2 to about 3 microns). As such, the capacitance of the p-n junctions in the active region may be relatively small, reducing the magnitude of the displacement current in the active region. However, in the portion of the inactive region beneath the gate structure, the above-discussed p-type silicon carbide region that is formed underneath the field insulating layer may have a length (in each horizontal direction) of, for example, about 100 to about 300 microns, and the displacement current generated in this region must flow to the source contacts of the unit cells closest to the portion of the inactive region of the semiconductor structure beneath the gate structure. As such, the capacitance of the p-n junction in the inactive region underneath the gate structure may be much larger, resulting in a significantly larger displacement current.

When the displacement current flows, a voltage is generated in the implanted region of the semiconductor structure. Pursuant to Ohm's law, a value of this voltage is equal to the product of the displacement current and the resistance of the semiconductor structure along the displacement current path. In silicon carbide-based semiconductor structures, implanted regions tend to have high sheet resistance. In the portion of the inactive region beneath the gate structure, the resistance may be high due to the implanted region underneath the field insulating layer and the capacitance of the p-n junction may be high for the reasons discussed above. As such, the displacement current flowing in the portion of the inactive region beneath the gate structure may generate high voltages in the semiconductor structure during device operation. If the generated voltage is sufficiently high, it may exceed the breakdown voltage of the field insulating layer. When this occurs, the field insulating layer may be damaged, which may result in device failure.

In some implementations, the field insulating layer may be relatively thick. For example, a thickness range for the field insulating layer might be between about 600 to about 800 nanometers, although other thicknesses may be used. However, at the edge of field insulating layer, a thin gate insulating pattern may be provided between the gate electrode pattern and the implanted region of the semiconductor layer structure. This gate insulating pattern may include, for example, a silicon oxide pattern, although other insulating materials may be used. The gate insulating pattern may be between the source contacts and the field insulating layer, and hence the displacement current generated in the portion of the inactive region beneath the gate structure may flow underneath the gate insulating pattern. This gate insulating pattern may be much thinner than the field insulating layer, having a thickness of, for example, between about 35 to about 50 nanometers. For silicon oxide, the breakdown voltage may be about 12 MV/cm multiplied by the thickness of the oxide. Thus, the breakdown voltage for a 600 nanometer thick silicon oxide field insulating layer would be about 720 Volts. In contrast, the breakdown voltage for a 35 nanometer thick silicon oxide gate insulating pattern would only be about 42 Volts. As a result, if the dV/dt levels experienced by the device are too high, then the device may be subject to failure due to breakdown of the thin gate insulating pattern that is provided adjacent to the field insulating layer.

The dV/dt capability of a semiconductor device refers to the amount of voltage change that the device may withstand within a given period of time. Silicon carbide power MOSFETs have been rated for dV/dt levels of about 30-80 V/nanosecond, and application of higher dV/dt levels may eventually result in device failure. To prevent the voltage generated in the thin gate insulating pattern that is adjacent to the field insulating layer from exceeding the breakdown voltage thereof the switching speed of the device may be limited (which reduces the displacement current).

In some cases, there may be significant displacement currents from an edge termination portion of an inactive region of a semiconductor structure. In some instances, power semiconductor devices (e.g., MOSFETs and IGBTs) may include one or more source runners located between, for instance, an edge termination portion and a gate runner of the gate structure on the power semiconductor device. The source runner may be around at least a part of a peripheral portion of the semiconductor device. The role of the source runner is to collect excessive displacement current and connect directly to source pad or source terminal so that the displacement current bypasses the active cells of the power semiconductor device.

In power semiconductor devices that use the MOSFET p-n junction body diode as free-wheeling diodes in a circuit, the p-n junction in the main active region provides the body diode current. The body diode current in the active region is collected in the wide body metal area, hence stress on the metal is very small. However, the body diode current in a portion of the semiconductor device where a source runner collects displacement current may be provided through a narrow-constricted bottleneck area, causing current density in the bottleneck area to be high. During body diode surge situations, with extremely high body diode current as well as high junction temperature of the device, the bottleneck area can burn out and cause device failure.

The source runner burn-out issue may be mitigated by replacing the source runner with a plurality of separated source/drain ohmic contacts formed through (or adjacent) the field insulating layer to provide a path for the displacement current that flows through the inactive region of the device. These additional source/drain ohmic contacts may be, for instance, referred to as “shunt contact structures” or “dV/dt mitigation structures.” The shunt contact structures may be placed inside the peripheral gate runners of the gate structure. The shunt contact structures are not one continuous contact to maintain metal connection between the gate runners and the active unit cells (e.g., through gate fingers) of the semiconductor device.

As a result of the shunt contact structures, the voltage levels applied to the thin gate insulating pattern may be significantly reduced, allowing for significantly higher displacement currents without risking device failure. Moreover, since the field insulating layer may be on the order of 10-20 times as thick as the thin gate insulating pattern, the field insulating layer may have a much higher breakdown voltage and hence can withstand the higher displacement currents and body diode surge currents.

The use of the shunt contact structures may alleviate the displacement current and body diode surge issues. However, the displacement current through an area of the semiconductor structure may depend on a size of the uncontacted area of the inactive region (e.g., highly doped p-region) that does not include a shunt contact structure in the region adjacent to the shunt contact structure. There may be increased uncontacted inactive region adjacent to a gate pad relative to a gate runner. In this regard, there may be greater displacement current through certain shunt contact structures (e.g., adjacent to the gate pad) relative to other shunt contact structures (e.g., adjacent to the peripheral gate runners).

According to example aspects of the present disclosure, a power semiconductor device may include a balancing shunt structure. The balancing shunt structure may reduce a difference between displacement currents through different shunt structures on the power semiconductor device.

For instance, a first shunt contact structure may provide a first shunt path for a first displacement current through a portion of the inactive region proximate, for instance, a gate pad. A second shunt contact structure may provide a second shunt path for a second displacement current through a portion of the inactive region proximate, for instance, a gate runner (e.g., a peripheral gate runner). The balancing shunt structure may reduce a difference between the first displacement current and the second displacement current by reducing a difference between effective resistance for the first displacement current and the second displacement current.

In some examples, the balancing shunt structure may be at least partially on the inactive region. For instance, the balancing shunt structure may form an ohmic contact with the inactive region of the semiconductor structure. The balancing shunt structure may between a gate runner and the edge termination portion.

In some examples, the plurality of shunt contact structures may be on a first side of a gate runner (e.g., toward an active region of the power semiconductor device). The balancing shunt structure may be on a second side of the gate runner (e.g., toward a peripheral portion of the power semiconductor device).

In some examples, the plurality of shunt contact structures may be electrically coupled to a source pad or a source contact for the power semiconductor device. The balancing shunt structure is not connected to the source pad or source contact or to any other metal structure of the power semiconductor device. In this way the balancing shunt structure may be operable to reduce a difference in effective resistance seen by displacement current across different portions of the inactive region and balance a displacement current among the plurality of shunt contact structures.

In some examples, the balancing shunt structure may be a balancing ring structure that is around at least a part of a peripheral portion of the semiconductor device. For instance, the balancing ring structure may at least partially surround one or more peripheral gate runners and a gate pad of the power semiconductor device. In some embodiments, the balancing ring structure may be discontinuous with one or more breaks. However, in some embodiments, the balancing ring structure is a continuous structure with no breaks located around the peripheral portion of the power semiconductor device.

In some embodiments, the power semiconductor device may include a gate pad in a center portion of the power semiconductor device. The power semiconductor device may include a pattern of shunt contact structures at least partially around the gate pad. The power semiconductor device may include a balancing shunt structure that includes a metal strip that extends in a direction away from the gate pad toward the peripheral portion of the power semiconductor device. In some examples, the balancing shunt structure may include a plurality of metal strip structures that form a grid. The shunt contact structures may be located along the plurality of metal strip structures. The balancing shunt structure can have other configurations for balancing a displacement current among a plurality of shunt contact structures on an inactive region without deviating from the scope of the present disclosure.

Aspects of the present disclosure provide a number of technical effects and benefits. For instance, the balancing shunt structure may balance displacement current between shunt contact structures used for dV/dt mitigation and used to address body diode surge current. The balancing shunt structure allows for removal of a source runner connected to a source contact to mitigate dV/dt effects from displacement current. The balancing shunt structure may allow gate runners to surround or encompass the entire active region of the power semiconductor device, which may lead to reduction in internal gate resistance and reduce uneven gate current distribution.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based transistor devices for purposes of illustration and discussion. Those of ordinary skill in the art, using the disclosures provided herein, will appreciate that certain aspects of the present disclosure may be applicable to other transistor devices without deviating from the scope of the present disclosure.

In the drawings and specification, there have been disclosed typical embodiments and, although specific terms are employed, they are used in a generic and descriptive sense only and not for purposes of limitation of the scope set forth in the following claims.

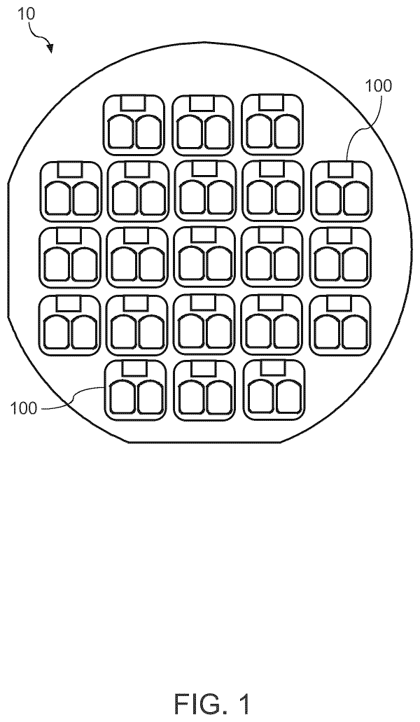

FIG. 1 is a plan view of a wafer 10 that includes a plurality of power semiconductor devices according to example embodiments of the present disclosure. Referring to FIG. 1, the wafer 10 may be a thin planar structure that includes a semiconductor structure with other material layers such as insulating layers and/or metal layers formed thereon. The semiconductor structure may include a semiconductor substrate and/or a plurality of other semiconductor layers. A plurality of semiconductor devices 100 may be formed in the wafer 10. The semiconductor devices 100 may be formed in rows and columns and may be spaced apart from each other so that the wafer 10 may later be subjected to a singulation process (e.g., diced) to separate the individual semiconductor devices 100 for packaging and testing. The wafer 10 may comprise a silicon carbide substrate having one or more silicon carbide layers formed thereon (e.g., by epitaxial growth) in some embodiments. Other semiconductor layers (e.g., polysilicon layers), insulating layers and/or metal layers may be formed on the silicon carbide semiconductor structure to form the power semiconductor devices 100. The silicon carbide substrate and the silicon carbide layers formed thereon may be 4H silicon carbide in some embodiments.

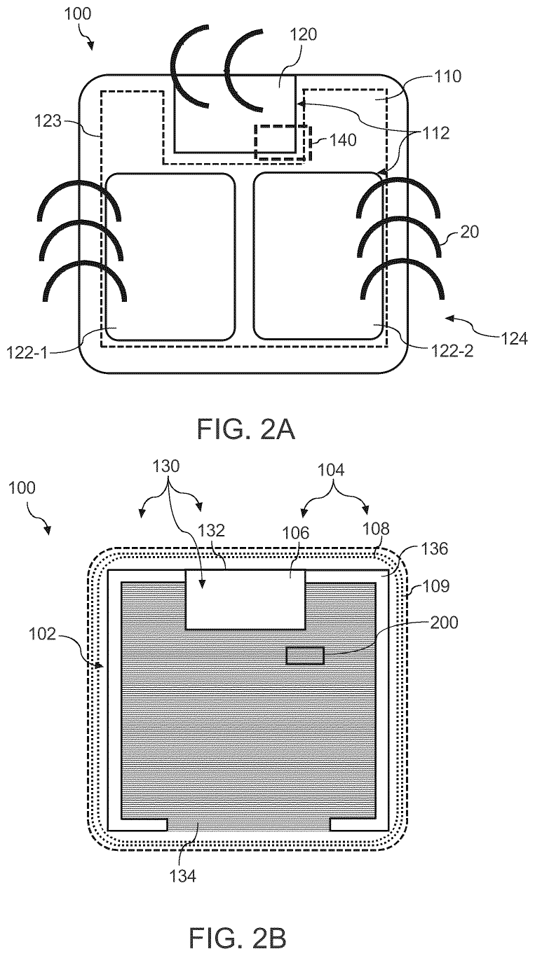

FIG. 2A is a plan view of one of the power semiconductor devices 100 included on the semiconductor wafer 10 of FIG. 1. FIG. 2B is a schematic plan view of the power semiconductor device 100 of FIG. 2A with the source and gate metallization removed. In the description below it is assumed that the power semiconductor device 100 is an n-type power MOSFET. However, those of ordinary skill in the art, using the disclosures provided herein, will understand that aspects of the present disclosure may be implement in a p-type power MOSFET or other semiconductor device (e.g., IGBT, Schottky diode, etc.) without deviating from the scope of the present disclosure.

As shown in FIG. 2A, a protective layer 110 covers a substantial portion of the top surface of the power semiconductor device 100. The protective layer 110 may be formed, for example, of polyamide. Various bond pads may be exposed through openings 112 in the protective layer 110. The bond pads may include a gate bond pad 120 and one or more source bond pads 122. Two source bond pads 122-1, 122-2 are illustrated in FIG. 2A. While not visible in FIG. 2A, a drain bond pad 124 may be provided on the bottom side of the power semiconductor device 100. The bond pads 120, 122, 124 may be formed of a metal, such as aluminum, that bond wires can be readily attached to via techniques such as thermo-compression or soldering. The bond pads may be coupled to terminals in a semiconductor package to provide a gate terminal, source terminal, and drain terminal respectively for the semiconductor device. As will be discussed in more detail below, source contacts are provided that contact a semiconductor structure of the power semiconductor device 100. The source contacts may be lower portions of a source metal pattern 123 that extends across much of the upper surface of the power semiconductor device 100 (e.g., all but the portion of the upper surface of the power semiconductor device 100 occupied by the gate bond pad 120). The source bond pads 122-1, 122-2 may include portions of the source metal pattern 123 that are exposed by the openings 112 in the protective layer 110. Bond wires 20 are shown in FIG. 2A that may be used to connect the gate bond pad 120 and the source bond pads 122-1, 122-2 to external voltage sources (not shown) such as terminals of other circuit elements.

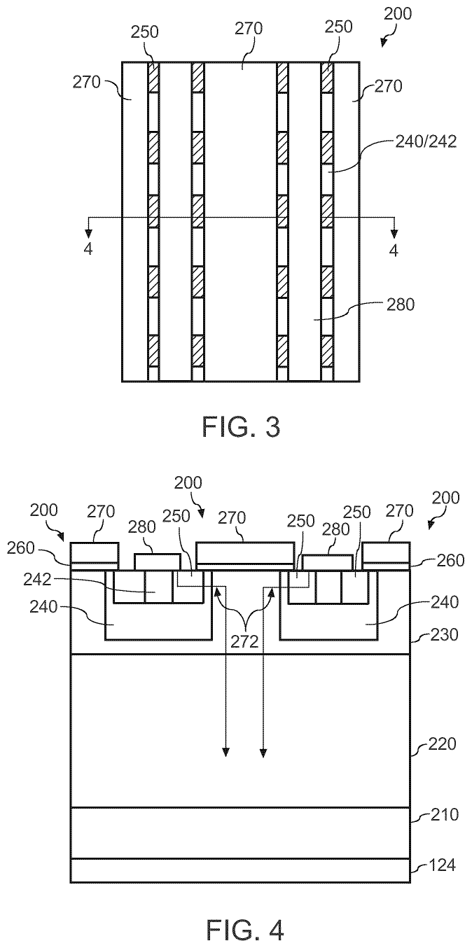

As is shown in FIG. 2B, the power semiconductor device 100 includes a semiconductor structure that includes an active region 102 and an inactive region 104. The active region 102 is an area of the device that includes operable transistors (e.g., the unit cell transistors discussed herein), while the inactive region 104 is an area that does not include such operable transistors. The unit cell transistors 200 (see FIGS. 3-4) of the power semiconductor device 100 are formed in the active region 102. The location of one unit cell 200 is shown by a box 200 in FIG. 2B to provide context. The active region 102 may generally correspond to the area under the source metal pattern 123 in some embodiments. The inactive region 104 includes a gate structure portion 106 and an edge termination portion 108. The gate structure portion 106 of the inactive region 104 may approximately correspond to the portion of the semiconductor structure that is underneath the certain portions of the gate structure of the semiconductor device. The edge termination portion 108 of the inactive region 104 may extend around a periphery of the power semiconductor device 100 and may include one or more termination structures such as guard rings and/or a junction termination extension that can reduce electric field crowding that may occur around the edge of the device. The termination structures (shown as guard rings 109) may spread out the electric fields along the periphery of the MOSFET, reducing electric field crowding. The edge termination structures may serve to increase the reverse blocking voltage at which a phenomenon known as “avalanche breakdown” occurs where an increasing electric field results in runaway generation of charge carriers within the semiconductor device, resulting in a sharp increase in current that may damage or even destroy the device.

As is further shown in FIG. 2B, a gate structure 130 (e.g., gate electrode pattern) may be provided that includes a gate pad 132, a plurality of gate fingers 134, and one or more gate runners 136 (e.g., gate buses) that electrically connect the gate fingers 134 to the gate pad 132. The gate pad 132 of the gate structure 130 may be underneath the gate bond pad 120. The gate runners 136 may include one or more peripheral gate runners on the inactive region 104. The gate runners 136 are peripheral gate runners that extend about or around at least a part of the peripheral portion of the semiconductor device 100. The gate fingers 134 may extend horizontally across the active region 102. An insulating layer (not shown) may cover the gate fingers 134 and gate runner(s) 136. The source metal pattern 123 may be provided over the gate fingers 134 and insulating layer, with the source contacts of the source metal layer contacting corresponding source regions in the semiconductor structure in openings between the gate fingers 134.

FIG. 3 is a schematic plan view of a portion of a unit cell 200 of the power semiconductor device 100 of FIGS. 2A-2B. FIG. 4 is a schematic cross-sectional diagram taken along the line 4-4 of FIG. 3 that illustrates the unit cell structure in an active region of the device. It will be appreciated that the specific layer structure, doping concentrations, materials, conductivity types and the like that are shown in FIGS. 3-4 and/or described below are merely provided as examples to illustrate in detail the structure of a specific example embodiment. Thus, the specific details discussed below are not limiting to the present disclosure.

Referring to FIGS. 2A, 2B, 3 and 4, the unit cell 200 is part of the active region 102 of the power semiconductor device 100. The unit cell 200 may be one of a plurality of unit cells 200 that are electrically disposed in parallel. It will be appreciated that FIG. 4 illustrates one full unit cell 200 and portions of two additional unit cells 200 on either side thereof in order to provide context.

As shown in FIGS. 3-4, the power semiconductor device 100, and hence the unit cell 200, includes an n-type wide band-gap semiconductor substrate 210. The substrate 210 may include, for example, a single crystal 4H silicon carbide semiconductor substrate. The substrate 210 may be heavily-doped with n-type impurities (i.e., an n+ silicon carbide substrate). The impurities may comprise, for example, nitrogen or phosphorus. The doping concentration of the substrate 210 may be, for example, between 1×10¹⁸ atoms/cm³ and 1×10²¹ atoms/cm³, although other doping concentrations may be used. The substrate 210 may be any appropriate thickness (e.g., between 100 and 500 microns thick.

A lightly-doped n-type (n) silicon carbide drift region 220 is provided on the substrate 210. The n-type silicon carbide drift region 220 may be formed by, for example, epitaxial growth on the silicon carbide substrate 210. The n-type silicon carbide drift region 220 may have, for example, a doping concentration of 1×10¹⁶ to 5×10¹⁷ dopants/cm³. The n-type silicon carbide drift region 220 may be a thick region, having a vertical height above the substrate 210 of, for example, 3-100 microns. An upper portion of the n-type silicon carbide drift region 220 may comprise an n-type silicon carbide current spreading layer 230 in some embodiments. The n-type silicon carbide current spreading layer 230 may be grown in the same processing step as the remainder of the n-type silicon carbide drift region 220 and may be considered to be part of the n-type silicon carbide drift region 220. The n-type current spreading layer 230 may be a moderately-doped current spreading layer 230 that has a doping concentration (e.g., doping concentration of 1×10¹⁶ to 5×10¹⁸ dopants/cm³) that exceeds the doping concentration of the remainder of the more lightly-doped n-type silicon carbide drift layer 220. The n-type current spreading layer 230 may be omitted in some embodiments.

An upper portion of the n-type current spreading layer 230 may be doped p-type by ion implantation to form p-wells 240. The p-wells 240 may have a doping concentration of, for example, between 5×10¹⁶/cm3 and 5×10¹⁹/cm³. An upper portion 242 of each p-well may be more heavily doped with p-type dopants. The upper portion 242 of each p-well 240 may have a doping concentration of, for example, between 2×10¹⁸/cm3 and 1×10²⁰/cm3. The p-wells 240 (including the more heavily-doped upper portions 242 thereof) may be formed by ion implantation. Ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer to a certain depth.

Heavily-doped (n+) n-type silicon carbide source regions 250 may be formed in upper portions of the p-wells 240 directly adjacent and contacting the more heavily doped portions 242 of the p-wells 240. The n-type source regions 250 may also be formed by ion implantation. The heavily-doped (n+) n-type silicon carbide regions 250 act as source regions for the unit cell transistor. The drift region 220/current spreading layer 230 and the substrate 210 together act as a common drain region for the power semiconductor device 100.

The n-type silicon carbide substrate 210, n-type silicon carbide drift region 220/current spreading layer 230, the p-wells 240, 242 and the n-type source regions 250 formed therein may together comprise a semiconductor structure of the semiconductor device 100.

A gate insulating pattern 260 may be on the upper surface of the semiconductor layer structure over the exposed portions of the current spreading layer 230 and extending onto the edges of the p-wells 240 and n-type source regions 250. The gate insulating pattern 260 may include, for example, a silicon oxide layer, although other insulating materials may be used. A gate finger 270 is on the gate insulating pattern 260. The gate finger 270 may correspond to one of the gate fingers 134 illustrated in FIG. 2B above. Accordingly, it will be appreciated that the gate finger 270 may be part of a continuous gate structure that includes the gate pad 132, one or more gate runners 136, and a plurality of gate fingers 270. In some embodiments, this gate structure may include, for example, a semiconductor pattern (e.g., polysilicon) or a metal gate pattern.

Source contacts 280 may be on the heavily-doped n-type source regions 250 and the more heavily-doped portions 242 of the p-wells. As described above with reference to FIGS. 2A-2B, the source contacts 280 may be part of a continuous source pattern 123 that extends across the upper surface of the silicon carbide semiconductor layer structure. The remainder of the source pattern 123 (as well as the insulating layer that electrically isolates the gate fingers 270 from the source pattern 123) is not shown in FIGS. 3-4 to simplify the drawings. The source contacts 280 may include, for example, metals such as nickel, titanium, tungsten or aluminum, or alloys or thin layered stacks of these or similar materials. As described above, a drain contact 124 may be on the lower surface of the substrate 210. The drain contact 124 may include, for example, similar materials to the source contact, as this forms an ohmic contact to the silicon carbide substrate. While the power semiconductor device 100 is an n-type device with the source contacts 280 on an upper surface thereof and the drain contact 124 on the bottom surface thereof, it will be appreciated that in p-type devices these locations are reversed.

Horizontal channel regions 272 are formed in the p-wells 240 adjacent to the gate insulating pattern 260. Current may flow from the n-type source regions 250 through the channel regions 272 to the portion of the drift region 220/current spreading layer 230 that is underneath the gate finger 270 when a voltage is applied to the gate fingers 270, as shown by the arrows in FIG. 4.

FIG. 4 depicts a unit cell with a gate finger 270 formed on top of the semiconductor structure for purposes of illustration and discussion. Alternatively, the unit cell may have the gate finger 270 at least partially in a gate trench within the semiconductor structure.

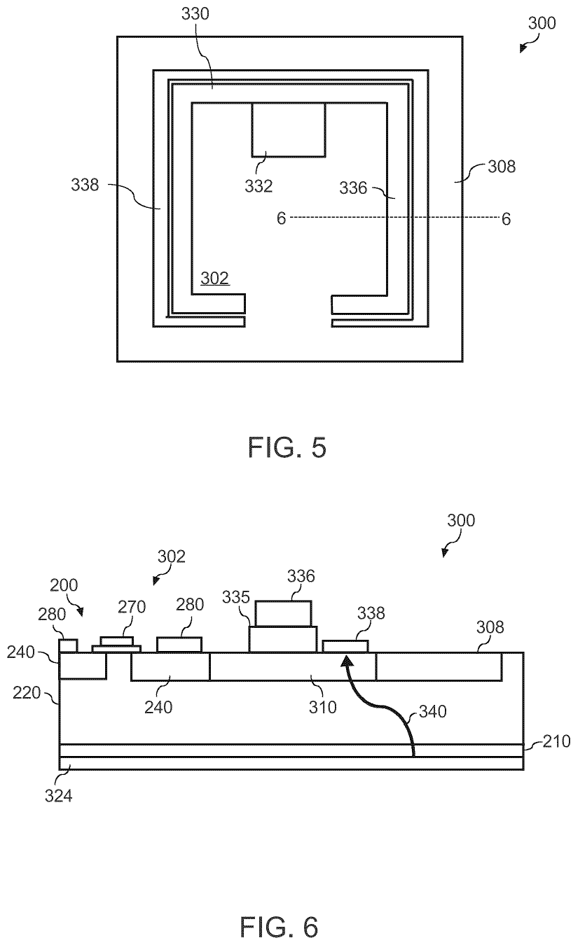

FIG. 5 depicts a plan view of an example power semiconductor device 300. FIG. 6 depicts a cross sectional view of the power semiconductor device 300 of FIG. 6 taken along line 6-6. The power semiconductor device 300 is similar to the power semiconductor device 100 shown in FIGS. 1-4. For instance, the power semiconductor device 300 includes an active region 302 with a plurality of unit cell devices. Each unit cell device may be, for instance, a silicon carbide-based MOSFET, such as the unit cell device 200 described with reference to FIG. 4. The power semiconductor device 300 includes an inactive region. The inactive region may be under the gate structure 330 and may include the edge termination region 308.

The power semiconductor device 300 includes a gate structure 330. The gate structure 330 includes a gate pad 332 and peripheral gate runners 336. The peripheral gate runners 336 may be located about or around at least a part of the peripheral portion of the power semiconductor device 300. As depicted in FIG. 6, the peripheral gate runners 336 may be on a field insulating layer 335. The field insulating layer 335 may be, for instance, an oxide layer, such as a SiOx layer. The thickness of the field insulating layer 335 under the gad pad portion 332 and the gate runner(s) 336 may be greater than a thickness of the gate insulating pattern 260 under the gate fingers 270 in the active region 302. A thickness of the field insulating layer 335 may be between about 600 to about 800 nanometers, although other thicknesses may be used without deviating from the scope of the present disclosure.

The field insulating layer 335 may be on a p-well region 310. The p-well region 310 may form a part of the inactive region of the semiconductor structure. The p-well region 310 may be of a second conductivity type that is different from a first conductivity type associated with a drift region 220 and the substrate 210. The p-well region 310 may have a doping concentration of, for example, between 5×10¹⁶/cm3 and 5×10¹⁹/cm3. The p-well region 310 may be formed by ion implantation.

As depicted in FIGS. 5 and 6, the power semiconductor device 300 may include a source runner 338 located adjacent to the peripheral gate runner 336. The source runner 338 may be coupled (e.g., conductively coupled) to, for instance, a source pad and/or source terminal associated with the power semiconductor device 300. The source runner 338 may be between the peripheral gate runner 336 and a peripheral edge of the semiconductor device 300. The source runner 338 may be between the peripheral gate runner and the edge termination region 308 of the power semiconductor device 300. The source runner 338 may be an ohmic contact with the p-well region 310 of the inactive region of the semiconductor structure. The source runner 338 may be nickel, titanium, tungsten, aluminum, or alloys or thin layered stacks of these or similar materials.

The source runner 338 may be used to protect the unit cells in the active region 302 from displacement current. For instance, as shown in FIG. 6, when the power semiconductor device 300 turns on, a displacement current 340 flows from the drain contact 324 to the source runner 338. In this way, the source runner 338 may provide a shunt path for displacement current that protects the unit cells of the active region 302 and other aspects of the power semiconductor device 300 from the displacement current 340. More particularly, the source runner 338 collects excessive displacement current, and connects directly to the source pad and/or source terminal for the semiconductor device 300, bypassing the unit cells in the active region 302.

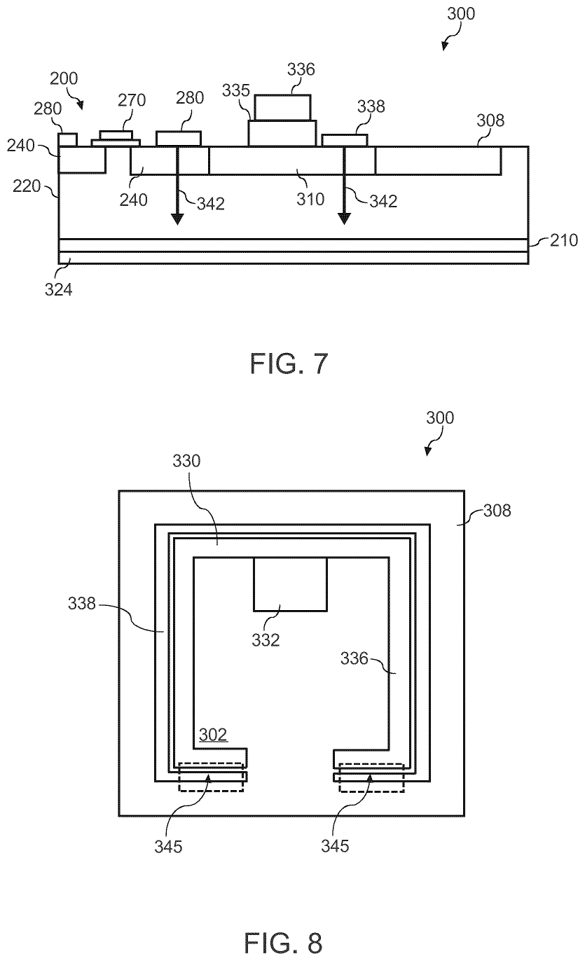

In some applications, the p-n junctions of the power semiconductor device 300 may be used as free-wheeling diodes in a power circuit. More particularly, as illustrated in FIG. 7, the p-n junctions in the unit cells in the active region 302 may provide the diode current 342 from the source contacts 280. However, the source runner 338 also contributes to the diode current 342 with the same current density. In the active region 302, the diode current 342 is collected in the main wide body metal of the source pads or source terminal for the power semiconductor device 300. However, the diode current 342 in the area of the source runner 338 may be collected and sent through a narrow and constricted bottle next area, such as the bottleneck areas 345 depicted in FIG. 8. Current density in the bottleneck areas 345 may be very high. During body diode surge situations, with extremely high body diode current as well as high junction temperature of the power semiconductor device 300, the bottleneck area 345 can burn out and cause performance degradation.

To address this issue, in some applications, a power semiconductor device may include a plurality of shunt contact structures or dV/dt mitigation structures instead of a source runner to provide a path for displacement current through the inactive region of the power semiconductor device and away from the unit cells of the active region. In some examples, the shunt contact structures may be placed inside the peripheral gate runners of the gate structure. The shunt contact structures are not one continuous contact to maintain metal connections between the gate runners and the active unit cells (e.g., through gate fingers) of the semiconductor device.

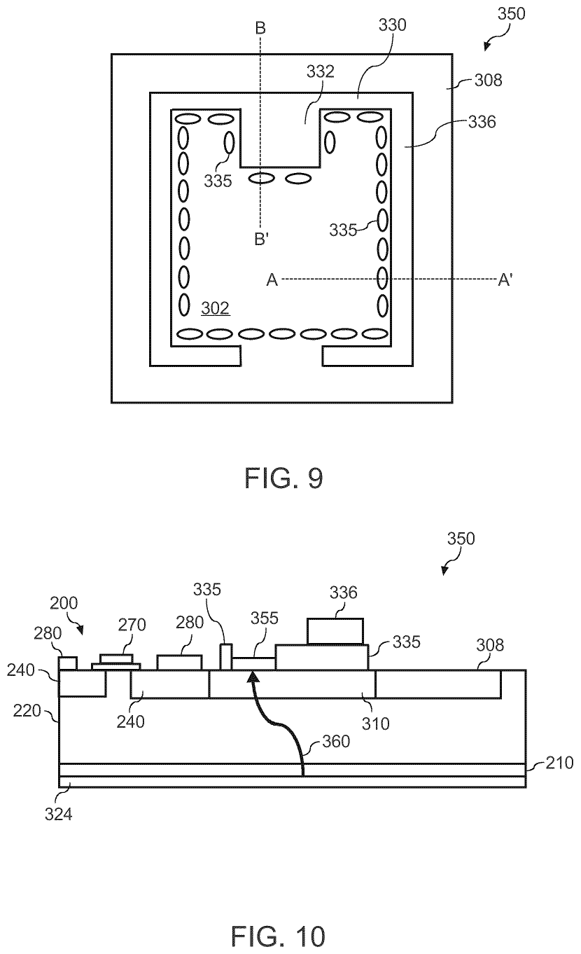

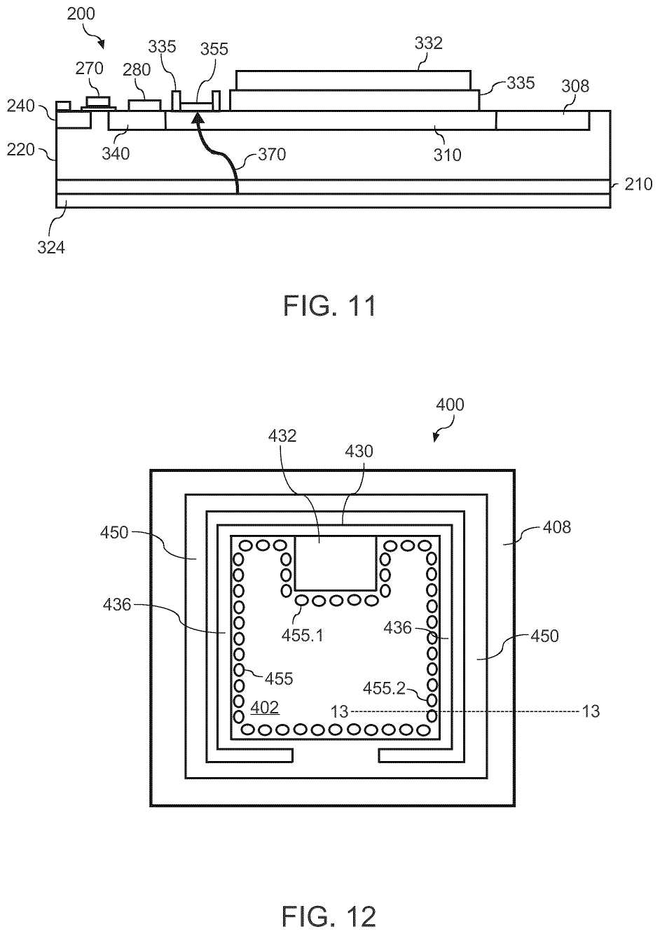

For example, FIG. 9 depicts a plan view of an example power semiconductor device 350 with a plurality of shunt contact structures 355 inside the peripheral gate runners 336. FIG. 10 depicts a cross-sectional view of the power semiconductor device 350 taken along line A-A′. FIG. 11 depicts a cross-sectional view of the power semiconductor device 350 taken along line B-B′. The power semiconductor device 350 does not include a source runner.

Similar to the power semiconductor device 300 of FIGS. 4-8, the power semiconductor device 350 includes an active region 302 with a plurality of unit cell devices. Each unit cell device may be, for instance, a silicon carbide-based MOSFET unit cell, such as the unit cell device 200 described with reference to FIG. 4. The power semiconductor device 350 includes an inactive region. The inactive region may include a region under at least a part of the gate structure 330 and may include the edge termination region 308.

The power semiconductor device 300 includes a gate structure 330. The gate structure 330 includes a gate pad 332 and peripheral gate runners 336. The peripheral gate runners 336 may be located about or around at least a part of the peripheral portion of the power semiconductor device 350. As depicted in FIG. 10, the peripheral gate runners 336 may be on a field insulating layer 335. As depicted in FIG. 11, the gate pad 332 may be on the field insulating layer 335. The field insulating layer 335 may be, for instance, an oxide layer, such as a SiOx layer. The thickness of the field insulating layer 335 under the gad pad portion 332 and the gate runner(s) 336 may be greater than a thickness of the gate insulating pattern 260 under the gate fingers in the active region 302. A thickness of the field insulating layer 335 may be between about 600 to about 800 nanometers, although other thicknesses may be used without deviating from the scope of the present disclosure.

The field insulating layer 335 may be on a p-well region 310. The p-well region 310 may form a part of the inactive region of the semiconductor structure. The p-well region 310 may be of a second conductivity type that is different from a first conductivity type associated with a drift region 220 and the substrate 210. The p-well region 310 may have a doping concentration of, for example, between 5×10¹⁶/cm³ and 5×10¹⁹/cm³. The p-well region 310 may be formed by ion implantation.

The shunt contact structures 355 may extend along an edge of the gate structure 330, including the gate pad 332 and the peripheral gate runners 336. For instance, the shunt contact structures 355 may be located adjacent to the peripheral gate runners 336 and the gate pad 332. For instance, the shunt contact structures 355 may be between the peripheral gate runners 336 and a center portion of the semiconductor device 350. The shunt contact structures 355 may be between the gate pad 332 and the center portion of the semiconductor device 350. As shown in FIG. 9, the plurality of shunt contact structures 355 may be in at least a partial ring arrangement adjacent to the gate structure 330. The plurality of shunt contact structures 355 are not one continuous contact (e.g., are separated structures) to accommodate electrical connections between the gate runners 336 and the gate fingers of the active region 302.

As shown in FIGS. 10 and 11, the shunt contact structures 355 may penetrate or extend through the field insulating layer 335. The shunt contact structures 355 may be an ohmic contact with the p-well region 310 of the inactive region of the semiconductor structure. Each of the plurality of shunt contact structures 355 may be conductively coupled to a source pad and/or source terminal for the power semiconductor device 350. The shunt contact structures 355 may be, for instance, nickel, titanium, tungsten, aluminum, or alloys or thin layered stacks of these or similar materials.

When the power semiconductor device 350 turns on, a displacement current 360 flows from the drain contact 324 through shunt paths in the plurality of shunt contact structures 355. In this way, each of the shunt contact structures 355 may provide a shunt path for displacement current that protects the unit cells of the active region 302 and other aspects of the power semiconductor device 300 from the displacement current 360.

The plurality of shunt contact structures 355 may alleviate body diode surge complications but may lead to uneven distribution of displacement current. For instance, FIG. 10 depicts a cross-sectional view of the power semiconductor device 350 that illustrates a shunt contact structure 355 adjacent to a gate runner 336. The shunt contact structure 355 in FIG. 10 provides a first shunt path for a first displacement current 360. FIG. 11 depicts a cross-sectional view of the power semiconductor structure 350 that illustrates a shunt contact structure 355 adjacent to the gate pad 332 of the gate structure 330. The shunt contact structure 355 provides a second shunt path for a second displacement current 370.

The magnitude of the displacement current may depend on a size of the p-well region 310 that is uncontacted by the shunt contact structures 355. The size of the p-well region 310 in the portion of the semiconductor device 350 adjacent to the gate pad 332 is greater than the size of the p-well region 310 in the portion of the semiconductor device 350 adjacent to the gate runners 336. In this regard, the displacement current 370 through the shunt path illustrated in FIG. 11 may be significantly greater than the displacement current 360 through the shunt path illustrated in FIG. 10.

According to example aspects of the present disclosure, a power semiconductor device may include a balancing shunt structure that balances or reduces a difference between the displacement currents through the different shunt paths through the shunt contact structures of the semiconductor device. The balancing shunt contact structure is not connected to a source terminal, source contact, gate terminal, gate structure, or other metal structure.

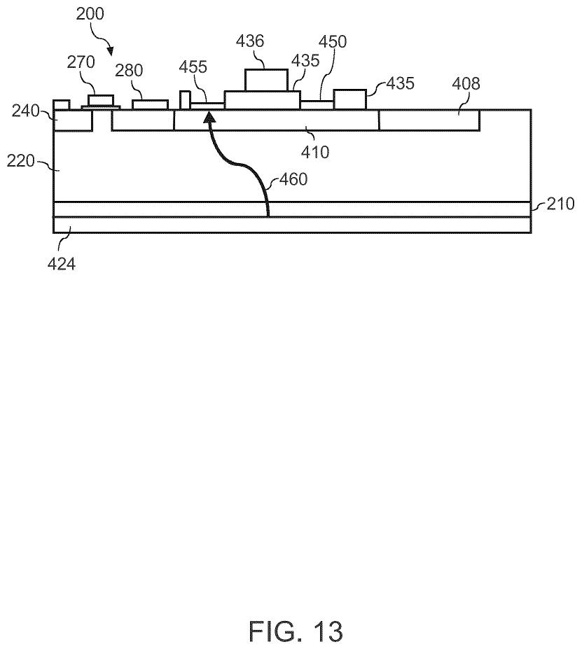

For example, FIG. 12 depicts a power semiconductor device 400 according to example embodiments of the present disclosure. FIG. 13 depicts a cross-sectional view of the power semiconductor device 400 taken along line 13-13. The power semiconductor device 400 does not include a source runner.

Similar to the power semiconductor device 300 of FIGS. 4-8, the power semiconductor device 400 includes an active region 302 with a plurality of unit cell devices. Each unit cell device may be, for instance, a silicon carbide-based MOSFET unit cell, such as the unit cell device 200 described with reference to FIG. 4. The power semiconductor device 400 includes an inactive region. The inactive region may be under a gate structure 430 and may include the edge termination region 408.

The power semiconductor device 400 includes a gate structure 430. The gate structure 430 includes a gate pad 432 and peripheral gate runners 436. The peripheral gate runners 436 may be located about or around at least a part of the peripheral portion of the power semiconductor device 400. As depicted in FIG. 13, the peripheral gate runners 436 may be on a field insulating layer 435. The field insulating layer 435 may be, for instance, an oxide layer, such as a SiOx layer. The thickness of the field insulating layer 435 under the gad pad portion 432 and the gate runner(s) 436 may be greater than a thickness of the gate insulating pattern 260 under the gate fingers in the active region 402. A thickness of the field insulating layer 435 may be between about 600 to about 800 nanometers, although other thicknesses may be used without deviating from the scope of the present disclosure.

The field insulating layer 435 may be on a p-well region 410. The p-well region 410 may form a part of the inactive region of the semiconductor structure. The p-well region 410 may be of a second conductivity type that is different from a first conductivity type associated with a drift region 220 and the substrate 210. The p-well region 310 may have a doping concentration of, for example, between 5×10¹⁶/cm3 and 5×10¹⁹/cm3. The p-well region 310 may be formed by ion implantation.

The shunt contact structures 455 may be located adjacent to the peripheral gate runners 436 and the gate pad 432. For instance, the shunt contact structures 455 may be between the peripheral gate runners 436 and a center portion of the semiconductor device 400. The shunt contact structures 455 may be between the gate pad 432 and the center portion of the semiconductor device 400. For instance, as shown in FIG. 12, the plurality of shunt contact structures 455 may be in at least a partial ring arrangement adjacent to the gate structure 430. The plurality of shunt contact structures 455 are not one continuous contact (e.g., are separated structures) to accommodate electrical connections between the gate runners 436 and the gate fingers of the active region 402.

As shown in FIG. 13, the shunt contact structures 455 may penetrate or extend through the field insulating layer 435. The shunt contact structures 455 may be an ohmic contact with the p-well region 410 of the inactive region of the semiconductor structure. Each of the plurality of shunt contact structures 455 may be electrically coupled to a source contact for the power semiconductor device 400. The shunt contact structures 455 may be, for instance, nickel, titanium, tungsten or aluminum, or alloys or thin layered stacks of these or similar materials.

The plurality of shunt contact structures 455 may include a first shunt contact structure 455.1 on the p-well region 410 and a second shunt contact structure 455.2 on the p-well region 410. The first shunt contact structure 455.1 may be adjacent to a gate runner 436. The second shunt contact structure 455.2 may be adjacent to a gate pad 432 of the gate structure 430. The first shunt contact structure 455.1 may provide a first shunt path for displacement current (e.g., displacement current 460 of FIG. 13). The second shunt contact structure 455.2 may provide a second shunt path for displacement current.

The power semiconductor device 400 includes a balancing shunt structure 450 at least partially on the inactive region (e.g., directly on the p-well region 410). The balancing shunt contact structure 450 may be directly on the p-well region 410. The balancing shunt structure 450 may provide an ohmic contact with the p-well region 410. The balancing shunt structure 450 is a conductive material, such as a metal. In some examples, the balancing shunt structure 450 is nickel, titanium, tungsten, aluminum, copper, gold, n- or p-type polysilicon, one or more metal silicides, or alloys or thin layered stacks of these or similar materials.

In some embodiments, the balancing shunt contact structure 450 is between the peripheral gate runners 436 and a peripheral edge of the semiconductor device 400. In some embodiments, the balancing shunt contact structure 450 is between the gate runner 436 and the edge termination region 408.

As shown in FIG. 13, the shunt contact structures 455 may be adjacent to a first side of the gate runner 436. The balancing shunt structure 450 may be adjacent to a second side of the gate runner 436 that is opposite the first side of the gate runner 436.

The balancing shunt structure 450 is not conductively coupled to the source pad or source terminal for the power semiconductor device 400. For instance, the shunt contact structures 455 (e.g., the first shunt contact structure 455.1 and the second shunt contact structure 455.2) may be conductively coupled to the source terminal or source pad for the power semiconductor device 400. However, the balancing shunt structure 450 is not coupled to the source terminal, source pad, gate structure 430, or any other metal structure.

The balancing shunt structure 450 is operable to balance the effective resistance of the shunt paths for the displacement current through the shunt contact structures 455. The balancing shunt structure 450 is coupled to inactive region (e.g., the p-well region 410) at locations near both the gate pad 432 and the gate runners 436 and effectively serves as a small parallel resistance, balancing out the effective resistance for the displacement current through the p-well region 410 in the portion of the semiconductor device 400 adjacent to the gate pad 432 and the p-well region 410 in the portion of the semiconductor device 400 adjacent to the gate runners 436. Accordingly, the balancing shunt structure 450 reduces a difference between displacement current through shunt paths in the different shunt contact structures 455 of the power semiconductor device 400. For instance, the balancing shunt structure 450 reduces a difference between a first displacement current through a first shunt contact structure 455.1 adjacent to the gate pad 432 and a second displacement current through a second shunt contact structure 455.2 adjacent to the gate runner 436.

The balancing shunt structure 450 in the example power semiconductor device 400 of FIGS. 11 and 12 is a balancing ring structure (e.g., an annular structure) that is located around at least a portion of the peripheral gate runner 436. The balancing ring structure 450 is a continuous ring structure on a peripheral portion of the power semiconductor device 400 without breaks. The balancing shunt structure 450 is illustrated as having sharp edges and corners. In some examples, the balancing shunt structure 450 may include one or more curved sections and/rounded corners. The balancing shunt structure 450 may have other suitable shapes or configurations without deviating from the scope of the present disclosure.

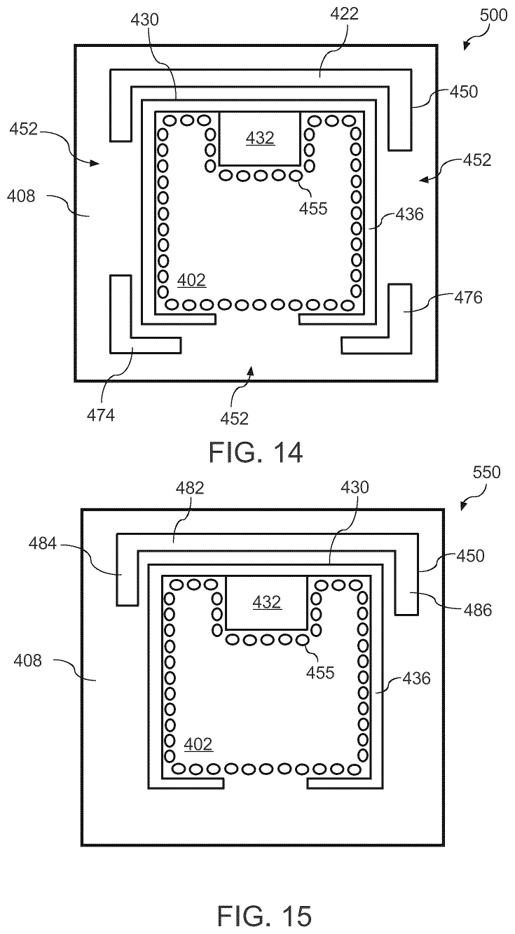

For instance, FIG. 14 depicts a plan view of an example power semiconductor device 500 according to examples embodiments of the present disclosure. The power semiconductor device 500 may be similar to the power semiconductor device 400 of FIGS. 12 and 13. However, the power semiconductor device 500 of FIG. 14 may include a balancing shunt structure 450 that is not a continuous ring structure. More particularly, the balancing shunt structure 450 is a discontinuous ring structure that has a plurality of breaks 452. A break 452 represents a gap in the balancing shunt structure 450. The balancing shunt structure may be around at least a part of a peripheral portion of the power semiconductor device 500. The power semiconductor device 500 does not include a source runner.

As depicted in FIG. 14, the balancing shunt structure may have a first portion 472 across a portion of the semiconductor device 100 adjacent to the gate pad 432. The first portion 472 of the balancing structure 450 may extend around corners of the peripheral gate runners 436 and/or the semiconductor device 500. The balancing shunt structure 450 may have a second portion 474 located in a corner of the power semiconductor device 500. The balancing shunt structure may have a third portion 476 located in another corner of the power semiconductor device 500. Each of the second portion 474 and the third portion 476 of the balancing shunt structure 450 may extend around a corner of the gate runners 436. The balancing shunt structure 450 of FIG. 14 may balance any difference in displacement currents in shunt paths through shunt structures 455 proximate the corners of the peripheral gate runners 436.

FIG. 15 depicts a plan view of an example power semiconductor device 550 according to examples embodiments of the present disclosure. The power semiconductor device 500 may be similar to the power semiconductor device 450 in FIG. 14. However, the power semiconductor device 550 of FIG. 15 may include a balancing shunt structure 450 that does not extend around the entirety of the gate structure 430. The balancing shunt structure 450 may have a conductive strip 482 that extends across a portion of the semiconductor device 100 adjacent to the gate pad 432. The balancing shunt structure 450 may include a first leg 484 extending from the conductive strip 482 (e.g., in a generally perpendicular direction). The balancing shunt structure 450 may include a second leg 486 extending from the conductive strip 482 (e.g., in a generally perpendicular direction). The first leg 484 and/or the second leg 486 may have longer or shorter lengths without deviating from the scope of the present disclosure. The power semiconductor device 550 does not include a source runner.

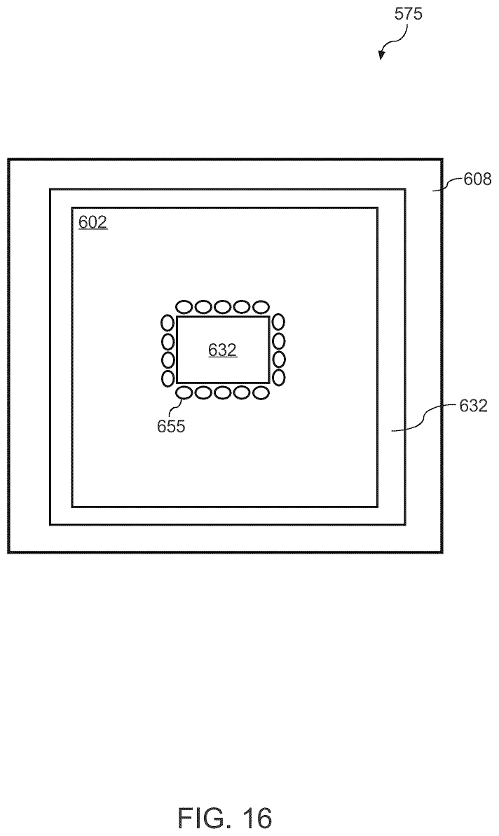

FIG. 16 depicts a plan view of an example power semiconductor device 575. For instance, the power semiconductor device 575 includes an active region 602 with a plurality of unit cell devices. Each unit cell device may be, for instance, a silicon carbide-based MOSFET unit cell, such as the unit cell device 200 described with reference to FIG. 4. The power semiconductor device 575 includes an inactive region. The inactive region may be under a gate structure and may include the edge termination region 608.

The power semiconductor device 575 includes a gate structure with a gate pad 632 in a center portion of the power semiconductor device 575. In some examples, the power semiconductor device may include one or more peripheral gate runners 636 around at least a part of the peripheral portion of the power semiconductor device 600. However, in some examples, there are no peripheral gate runners. Similar to the examples described above, the gate structure including the gate pad 632 and/or the peripheral gate runners 636 may be on a field insulating layer and may be on a p-well region of the semiconductor device 575. The power semiconductor device 575 does not include a source runner.

The power semiconductor device 575 may include a plurality of shunt contact structure 655 around at least a portion of the gate pad 632 (e.g., in a ring around the gate pad 632 in the center portion of the semiconductor device 575). The shunt contact structures 655 may directly contact the p-well region of the semiconductor device 600. The shunt contact structures 655 may provide an ohmic contact with the semiconductor structure of the semiconductor device 600. The shunt contact structures 655 may be between the gad pad portion 632 and the peripheral gate runner 636. The shunt contact structures 655 may be coupled to a source terminal or source pad for the power semiconductor device 650. The shunt contact structures 655 provide a shunt path for displacement current.

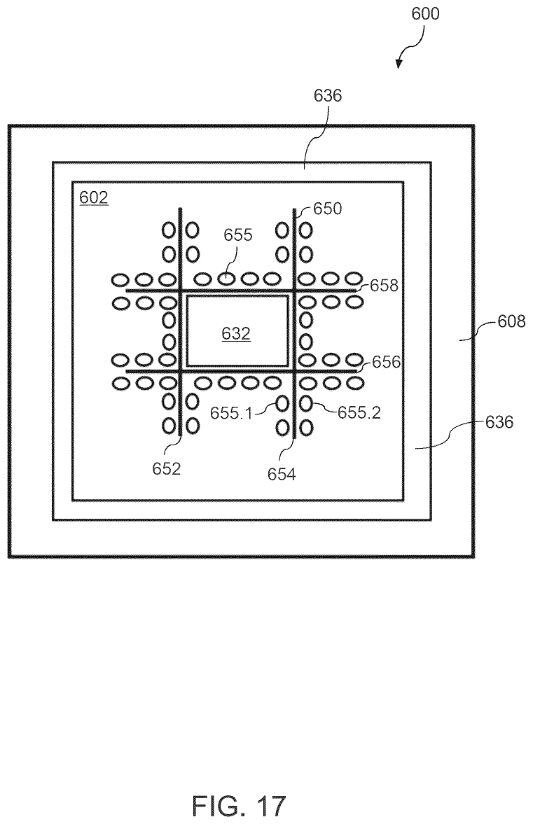

FIG. 17 depicts a plan view of an example power semiconductor device 600. For instance, the power semiconductor device 600 includes an active region 602 with a plurality of unit cell devices. Each unit cell device may be, for instance, a silicon carbide-based MOSFET unit cell, such as the unit cell device 200 described with reference to FIG. 4. The power semiconductor device 600 includes an inactive region. The inactive region may be under a gate structure and may include the edge termination region 608.

The power semiconductor device 600 includes a gate structure with a gate pad 632 in a center portion of the power semiconductor device 600. In some examples, the power semiconductor device may include one or more peripheral gate runners 636 around at least a part of the peripheral portion of the power semiconductor device 600. However, in some examples, there are no peripheral gate runners. Similar to the examples described above, the gate structure including the gate pad 632 and/or the peripheral gate runners 636 may be on a field insulating layer and may be on a p-well region of the semiconductor device 600.

According to example embodiments, the power semiconductor device 600 may include a plurality of shunt contact structures 655. The shunt contact structures 655 may directly contact the p-well region of the semiconductor device 600. The shunt contact structures 655 may provide an ohmic contact with the semiconductor structure of the semiconductor device 600. The shunt contact structures 655 may be between the gad pad portion 632 and the peripheral gate runner 636. The shunt contact structures 655 may be coupled to a source terminal or source pad for the power semiconductor device 650. The shunt contact structures 655 provide a shunt path for displacement current.

The power semiconductor device 600 includes a balancing shunt structure 650. The balancing shunt structure 650 may be between the gad pad portion 632 and the peripheral gate runner 636. The balancing shunt structure 650 in the example of FIG. 6 includes one or more metal strips extending at least partially from the gate pad 632 toward a peripheral portion of the semiconductor device. The balancing shunt structure 650 may balance displacement current through the plurality of shunt contact structures 655. The balancing shunt structure 650 is a conductive material, such as a metal. In some examples, the balancing shunt structure 650 is nickel, titanium, tungsten, aluminum, copper, gold, n- or p-type polysilicon, one or more metal silicides, or alloys or thin layered stacks of these or similar materials.

The balancing shunt structure 650 includes a plurality of metal strips that intersect so that the metal strips are arranged in a grid around the gate pad 632. For instance, the balancing shunt structure 650 includes a first metal strip 652 extending in a direction parallel to a first side of the gate pad 632. The balancing shunt structure 650 includes a second metal strip 654 extending in a direction parallel to a second side of the gate pad 632. The balancing shunt structure 650 includes a third metal strip 656 extending in a direction parallel to a third side of the gate pad 632. The balancing shunt structure includes a fourth metal strip 658 extending in a direction parallel to a fourth side of the gate pad 632. The first metal strip 652 and the second metal strip 654 intersect the third metal 656 strip at different locations. The first metal strip 652 and the second metal strip 654 intersect the fourth metal strip 658 at different locations. The first metal strip 652 and the second metal strip 654 do not intersect and/or may be generally parallel to one another. The third metal strip 656 and the fourth metal strip 658 do not intersect and/or may be generally parallel to one another.

The plurality of shunt contact structures 655 may be arranged along the metal strips of the balancing shunt structure 650. For instance, in some examples, the plurality of shunt contact structures may include one or more first shunt contact structure 655.1 on a first side of one of the plurality of metal strips (e.g., metal strip 654). The plurality of shunt contact structures 655 may include one or more second shunt contact structures 655.2 on a second side of one of the plurality of metal strips (e.g., metal strip 654) that is opposite the first side. In some examples, at least some of the plurality of shunt contact structures 650 may be located at different distances from the gate pad 632. For instance, the first shunt contact structure 655.1 is located a different distance from the gate pad 632 relative to the second shunt contact structure 655.2.

As discussed above, the plurality of shunt contact structures 655 may be coupled to the source pad of the power semiconductor device 600. The balancing shunt structure 650 is not coupled to the source pad, the gate structure, or any other metal structure of the power semiconductor device 600. The power semiconductor device 600 does not include a source runner.

One example embodiment of the present disclosure is directed to a power semiconductor device. The power semiconductor device includes a semiconductor structure comprising an active region and an inactive region, the active region comprising a plurality of unit cells. The power semiconductor device includes a gate structure, wherein at least a portion of the gate structure is on the inactive region. The power semiconductor device includes a first shunt contact structure at least partially on the inactive region. The power semiconductor device includes a second shunt contact structure at least partially on the inactive region. The power semiconductor device includes a balancing shunt structure at least partially on the inactive region.

In some embodiments, the first shunt contact structure provides a first shunt path for a first displacement current through the inactive region, wherein the second shunt contact structure provides a second shunt path for a second displacement current through the inactive region, wherein the balancing shunt structure reduces a difference between the first displacement current through the first shunt path and the second displacement current through the second shunt path.

In some embodiments, the first shunt contact structure is adjacent a first side of the gate structure and the balancing shunt structure is adjacent a second side of the gate structure, the second side being opposite the first side.

In some embodiments, the balancing shunt structure is between the gate structure and an edge termination region.

In some embodiments, at least a portion of the balancing shunt structure is directly on the inactive region of the semiconductor structure.

In some embodiments, the first shunt contact structure and the second shunt contact structure are coupled to a source terminal for the power semiconductor device.

In some embodiments, the balancing shunt structure is not coupled to the source terminal.

In some embodiments, the gate structure comprises a gate pad and a gate runner.

In some embodiments, the first shunt contact structure is adjacent to the gate pad and the second shunt contact structure is adjacent to the gate runner.

In some embodiments, the gate runner is a peripheral gate runner located around at least a part of a peripheral portion of the power semiconductor device.

In some embodiments, the balancing shunt structure comprises a balancing ring structure located around at least a portion of the peripheral gate runner.

In some embodiments, the balancing ring structure comprises a discontinuous ring structure with one or more breaks.

In some embodiments, the balancing ring structure is a continuous structure with no breaks.

In some embodiments, the gate pad is located in a peripheral portion of the power semiconductor device.

In some embodiments, the gate pad is located in a center portion of the power semiconductor device.

In some embodiments, the first shunt contact structure is located a first distance from the gate pad and the second shunt contact structure is located a second distance from the gate pad, the first distance being different from the second distance.

In some embodiments, at least a portion of the balancing shunt structure is between the first shunt contact structure and the second shunt contact structure.

In some embodiments, at least a portion of the balancing shunt structure is between the gate pad and the first shunt contact structure.

In some embodiments, the balancing shunt structure comprises a plurality of metal strips, the plurality of metal strips intersecting one another.

In some embodiments, the semiconductor device further comprises a field insulating layer on at least a portion of the inactive region.

In some embodiments, the field insulating layer is between at least a portion of the gate structure and the inactive region.

In some embodiments, the first shunt contact structure, the second shunt contact structure, and the balancing shunt structure extend through the field insulating layer.

In some embodiments, the power semiconductor device does not have a source runner in a peripheral portion of the power semiconductor device.

In some embodiments, the first shunt contact structure and the second shunt contact structure are a part of a plurality of shunt contact structures that are in at least a partial ring arrangement adjacent to the gate structure.

In some embodiments, the semiconductor structure comprises a wide bandgap semiconductor.

In some embodiments, the semiconductor structure comprises silicon carbide.

In some embodiments, the plurality of unit cells comprise one or more silicon carbide-based MOSFET transistor cells.

Another example embodiment of the present disclosure is directed to a power semiconductor device. The power semiconductor device includes a semiconductor structure comprising an active region and an inactive region, the active region comprising a plurality of unit cells. The power semiconductor device includes a field insulating layer at least partially on the inactive region. The power semiconductor device includes a gate structure at least partially on the field insulating layer. The power semiconductor device includes a shunt contact structure extending at least partially through the field insulating layer. The power semiconductor device includes a balancing shunt structure at least partially on the inactive region.

In some embodiments, the shunt contact structure is electrically coupled to a source pad for the power semiconductor device and the balancing shunt structure is not electrically coupled to the source pad.

In some embodiments, the balancing shunt structure comprises a balancing ring structure located about at least a portion of a gate runner.

In some embodiments, the balancing ring structure comprises a discontinuous ring structure with one or more breaks.

In some embodiments, the balancing ring structure is a continuous ring structure with no breaks.

In some embodiments, the balancing shunt structure is between the gate structure and an edge termination region.

In some embodiments, at least a portion of the balancing shunt structure directly contacts the inactive region of the semiconductor structure.

In some embodiments, the balancing shunt structure is operable to reduce a resistance associated with the shunt contact structure.

In some embodiments, the balancing shunt structure is a metal strip between a gate pad and a peripheral portion of the power semiconductor device.

In some embodiments, the semiconductor structure comprises a wide bandgap semiconductor.

In some embodiments, the semiconductor structure comprises silicon carbide.

In some embodiments, the plurality of unit cells comprise one or more silicon carbide-based MOSFET transistor cells.

Another example embodiment of the present disclosure is directed to a power semiconductor device. The power semiconductor device includes a semiconductor structure comprising an active region and an inactive region, the active region comprising a plurality of unit cells. The power semiconductor device includes a gate structure, wherein at least a portion of the gate structure is on the inactive region. The power semiconductor device includes a plurality of shunt contact structures at least partially on the inactive region. The power semiconductor device includes a balancing shunt structure at least partially on the inactive region. The balancing shunt structure is operable to balance a displacement current associated with the plurality of shunt contact structures.

In some embodiments, the plurality of shunt contact structures is adjacent a first side of the gate structure and the balancing shunt structure is adjacent a second side of the gate structure, the second side being opposite the first side.

In some embodiments, the balancing shunt structure is between the gate structure and an edge termination region.

In some embodiments, at least a portion of the balancing shunt structure is directly on the inactive region.

In some embodiments, the plurality of shunt contact structures are electrically coupled to a source pad for the power semiconductor device and the balancing shunt structure is not electrically coupled to the source pad.

In some embodiments, the gate structure comprises a gate pad and a gate runner.

In some embodiments, the plurality of shunt contact structures comprise a first shunt contact structure adjacent to the gate pad and a second shunt contact structure adjacent to the gate runner.

In some embodiments, the gate runner is a peripheral gate runner located about at least a part of a peripheral portion of the power semiconductor device.

In some embodiments, the balancing shunt structure comprises a balancing ring structure located about at least a portion of the peripheral gate runner.

In some embodiments, the balancing ring structure comprises a discontinuous ring structure with one or more breaks.

In some embodiments, the balancing ring structure is a continuous structure with no breaks.

In some embodiments, the gate pad is located in a peripheral portion of the power semiconductor device.

In some embodiments, the gate pad is located in a center portion of the power semiconductor device.

In some embodiments, the balancing shunt structure comprises a plurality of metal strips arranged in a grid.

In some embodiments, the semiconductor device comprises a field insulating layer on at least a portion of the inactive region.

In some embodiments, the field insulating layer is between at least a portion of the gate structure and the inactive region.

In some embodiments, the plurality of shunt contact structures and the balancing shunt structure extend through the field insulating layer.

In some embodiments, the power semiconductor device does not include a source runner.

In some embodiments, the plurality of shunt contact structures are in at least a partial ring arrangement adjacent to the gate structure.

In some embodiments, the semiconductor structure comprises a wide bandgap semiconductor.

In some embodiments, the semiconductor structure comprises silicon carbide.

In some embodiments, the plurality of unit cells comprise one or more silicon carbide-based MOSFET transistor cells.

Another example embodiment of the present disclosure is directed to power semiconductor device. The power semiconductor device includes a semiconductor structure comprising an active region and an inactive region, the active region comprising a plurality of unit cells. The power semiconductor device includes a gate pad in a center portion of the power semiconductor device. The power semiconductor device includes a plurality of shunt contact structures at least partially around the gate pad.

In some embodiments, the semiconductor device comprises a balancing shunt structure, the balancing shunt structure comprising a metal strip between the gate pad and a peripheral portion of the power semiconductor device.

In some embodiments, the balancing shunt structure comprises a plurality of metal strips between the gate pad and the peripheral portion of the power semiconductor device.

In some embodiments, the plurality of metal strips comprise a first metal strip and a second metal strip, the first metal strip and the second metal strip intersecting one another.

In some embodiments, the power semiconductor device comprises a plurality of shunt contact structures extending along at least a portion of the metal strip.

In some embodiments, the plurality of shunt contact structures are electrically coupled to a source terminal for the power semiconductor device and the balancing shunt structure is not electrically coupled to the source terminal.

In some embodiments, the plurality of shunt contact structures comprise a first shunt contact structures located a first distance from the gate pad and a second shunt contact structure is located a second distance from the gate pad, the first distance being different from the second distance.

In some embodiments, the plurality of shunt contact structures comprise a first shunt contact located on a first side of the metal strip and a second shunt contact structure located on a second side of the metal strip, the first side being opposite the second side.

In some embodiments, the metal strip is one of a plurality of metal strips, the plurality of metal strips comprising: a first metal strip extending in a direction parallel to a first side of the gate pad; a second metal strip extending in a direction parallel to a second side of the gate pad; a third metal strip extending in a direction parallel to a third side of the gate pad; and a fourth metal strip extending in a direction parallel to a fourth side of the gate pad.

In some embodiments, the first metal strip and the second metal strip intersect the third metal strip at different locations, wherein the first metal strip and the second metal strip intersect the fourth metal strip at different locations, wherein the first metal strip and the second metal strip do not intersect, wherein the third metal strip and the fourth metal strip do not intersect.

In some embodiments, the semiconductor structure comprises a wide bandgap semiconductor.

In some embodiments, the semiconductor structure comprises silicon carbide.

In some embodiments, the plurality of unit cells comprise one or more silicon carbide-based MOSFET transistor cells.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A power semiconductor device, comprising:
a semiconductor structure comprising an active region and an inactive region, the active region comprising a plurality of unit cells;
a gate structure, wherein at least a portion of the gate structure is on the inactive region;
a first shunt contact structure at least partially on the inactive region;
a second shunt contact structure at least partially on the inactive region; and
a balancing shunt structure at least partially on the inactive region.

2. The power semiconductor device of claim 1, wherein the first shunt contact structure provides a first shunt path for a first displacement current through the inactive region, wherein the second shunt contact structure provides a second shunt path for a second displacement current through the inactive region, wherein the balancing shunt structure reduces a difference between the first displacement current through the first shunt path and the second displacement current through the second shunt path.

3. The power semiconductor device of claim 1, wherein the first shunt contact structure is adjacent a first side of the gate structure and the balancing shunt structure is adjacent a second side of the gate structure, the second side being opposite the first side.

4. The power semiconductor device of claim 1, wherein the balancing shunt structure is between the gate structure and an edge termination region.

5. The power semiconductor device of claim 1, wherein at least a portion of the balancing shunt structure is directly on the inactive region of the semiconductor structure.

6. The power semiconductor device of claim 1, wherein the first shunt contact structure and the second shunt contact structure are coupled to a source terminal for the power semiconductor device, wherein the balancing shunt structure is not coupled to the source terminal.

7. (canceled)

8. The power semiconductor device of claim 1, wherein the gate structure comprises a gate pad and a gate runner.

9. The power semiconductor device of claim 8, wherein the first shunt contact structure is adjacent to the gate pad and the second shunt contact structure is adjacent to the gate runner.

10. The power semiconductor device of claim 8, wherein the gate runner is a peripheral gate runner located around at least a part of a peripheral portion of the power semiconductor device.

11. The power semiconductor device of claim 10, wherein the balancing shunt structure comprises a balancing ring structure located around at least a portion of the peripheral gate runner.

12. The power semiconductor device of claim 11, wherein the balancing ring structure comprises a discontinuous ring structure with one or more breaks.

13. The power semiconductor device of claim 11, wherein the balancing ring structure is a continuous structure with no breaks.

14. The power semiconductor device of claim 8, wherein the gate pad is located in a peripheral portion of the power semiconductor device.

15. The power semiconductor device of claim 8, wherein the gate pad is located in a center portion of the power semiconductor device.

16. The power semiconductor device of claim 15, wherein the first shunt contact structure is located a first distance from the gate pad and the second shunt contact structure is located a second distance from the gate pad, the first distance being different from the second distance.

17. The power semiconductor device of claim 16, wherein at least a portion of the balancing shunt structure is between the first shunt contact structure and the second shunt contact structure.

18. The power semiconductor device of claim 16, wherein at least a portion of the balancing shunt structure is between the gate pad and the first shunt contact structure.

19. The power semiconductor device of claim 16, wherein the balancing shunt structure comprises a plurality of metal strips, the plurality of metal strips intersecting one another.

20. The power semiconductor device of claim 1, further comprising a field insulating layer on at least a portion of the inactive region, wherein the field insulating layer is between at least a portion of the gate structure and the inactive region, wherein the first shunt contact structure, the second shunt contact structure, and the balancing shunt structure extend through the field insulating layer.

21. (canceled)

22. (canceled)

23. The power semiconductor device of claim 1, wherein the power semiconductor device does not have a source runner in a peripheral portion of the power semiconductor device.

24. The power semiconductor device of claim 1, wherein the first shunt contact structure and the second shunt contact structure are a part of a plurality of shunt contact structures that are in at least a partial ring arrangement adjacent to the gate structure.

25. The power semiconductor device of claim 1, wherein the semiconductor structure comprises a wide bandgap semiconductor.

26. The power semiconductor device of claim 1, wherein the semiconductor structure comprises silicon carbide.

27. The power semiconductor device of claim 1, wherein the plurality of unit cells comprise one or more silicon carbide-based MOSFET transistor cells.

28. A power semiconductor device, comprising:
a semiconductor structure comprising an active region and an inactive region, the active region comprising a plurality of unit cells;
a field insulating layer at least partially on the inactive region;
a gate structure at least partially on the field insulating layer;
a shunt contact structure extending at least partially through the field insulating layer; and
a balancing shunt structure at least partially on the inactive region.

29.-39. (canceled)

40. A power semiconductor device, comprising:
a semiconductor structure comprising an active region and an inactive region, the active region comprising a plurality of unit cells;
a gate structure, wherein at least a portion of the gate structure is on the inactive region;
a plurality of shunt contact structures at least partially on the inactive region; and
a balancing shunt structure at least partially on the inactive region; and
wherein the balancing shunt structure is operable to balance a displacement current associated with the plurality of shunt contact structures.

41.-74. (canceled)
